(19) United States
(12) Patent Application Publication
(10) Pub. No.: US 2026/0229162 A1
(43) Pub. Date: Aug. 6, 2026

(54) SHIFT REGISTER, DRIVING METHOD, GATE DRIVING CIRCUIT AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yipeng Chen, Beijing (CN); Ling Shi, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 19/151,425

(22) PCT Filed: Jun. 12, 2024
(86) PCT No.: PCT/CN2024/098536

§ 371 Date: Jul. 28, 2025

(30) Foreign Application Priority Data
Jul. 20, 2023 (CN) 202310897092.7

(51) Int. Cl. G09G 3/20

(52) U.S. Cl. CPC G09G 3/2096; G09G 2300/0408; G09G 2310/0267; G09G 2310/0286; G09G 2330/023

(57) ABSTRACT

A shift register, a driving method, a gate driving circuit and a display device are provided. In the shift register, a first maintenance sub-circuit is coupled to a control signal input end and a first node, and configured to substantially maintain a voltage at the first node in a first operating mode. A second maintenance sub-circuit is coupled to the control signal input end and a second node, and configured to substantially maintain a voltage at the second node in the first operating mode.

### CROSS-REFERENCE TO RELATED APPLICATION

This application claims a priority of the Chinese patent application No. 202310897092.7 filed on Jul. 20, 2023, which is incorporated herein by reference in its entirety.

### TECHNICAL FIELD

The present disclosure relates to the field of display technology, in particular to a shift register, a driving method, a gate driving circuit and a display device.

### BACKGROUND

Along with the continuous development of the display technology, a display product is applied to in more fields, and correspondingly the display product is highly demanded. In order to meet a user's requirement on a narrow bezel of the display product, a Gate On Array (GOA) technology is adopted by the display product, i.e., a gate driving circuit is formed on an array substrate of the display product.

Power consumption of the display product mainly includes two parts, one being generated by a pixel driving circuit, and the other being generated by the gate driving circuit. In the related art, a corresponding technical method has been used to remarkably reduce the power consumption generated by the pixel driving circuit. Hence, there is an urgent need to reduce the power consumption generated by the gate driving circuit, thereby to reduce the overall power consumption of the display substrate.

### SUMMARY

An object of the present disclosure is to provide a shift register, a driving method, a gate driving circuit and a display device, so as to solve the above-mentioned problem.

In order to achieve the above-mentioned purpose, the present disclosure provides the following technical solutions.

In one aspect, the present disclosure provides in some embodiments a shift register, including a first node, a second node, a first output sub-circuit, and a second output sub-circuit. The shift register further includes a first maintenance sub-circuit and/or a second maintenance sub-circuit; the first output sub-circuit is coupled to a first level signal input end, a gate driving signal output end and the first node, and configured to control the first level signal input end to be electrically coupled to or electrically decoupled from the gate driving signal output end under the control of the first node; the second output sub-circuit is coupled to a first clock signal input end, the gate driving signal output end and the second node, and configured to control the first clock signal input end to be electrically coupled to or electrically decoupled from the gate driving signal output end under the control of the second node; the first maintenance sub-circuit is coupled to a control signal input end and the first node, and configured to substantially maintain a voltage at the first node in a first operating mode; and the second maintenance sub-circuit is coupled to the control signal input end and the second node, and configured to substantially maintain a voltage at the second node in the first operating mode.

In a possible embodiment of the present disclosure, the shift register further includes a third node, a fourth node, a third node control sub-circuit and a fourth node control sub-circuit, the third node control sub-circuit is configured to control a potential at the third node, and the fourth node control sub-circuit is configured to control a potential at the fourth node; the first maintenance sub-circuit includes a tenth transistor, a gate electrode of the tenth transistor is coupled to the control signal input end, a first electrode of the tenth transistor is coupled to the first node, and a second electrode of the tenth transistor is coupled to the third node; and the second maintenance sub-circuit includes a ninth transistor, a gate electrode of the ninth transistor is coupled to the control signal input end, a first electrode of the ninth transistor is coupled to the second node, and a second electrode of the ninth transistor is coupled to the fourth node.

In a possible embodiment of the present disclosure, the ninth transistor and the tenth transistor include oxide transistors.

In a possible embodiment of the present disclosure, the shift register further includes a fourth node and a fourth node control sub-circuit, and the fourth node control sub-circuit is configured to control a potential at the fourth node; the shift register further includes a third maintenance sub-circuit, and the third maintenance sub-circuit is coupled to a second level signal input end, the fourth node and the second maintenance sub-circuit, and configured to control the fourth node to be electrically coupled to or electrically decoupled from the second maintenance sub-circuit under the control of the second level signal input end.

In a possible embodiment of the present disclosure, the third maintenance sub-circuit includes an eighth transistor, a gate electrode of the eighth transistor is coupled to the second level signal input end, a first electrode of the eighth transistor is coupled to the second maintenance sub-circuit, and a second electrode of the eighth transistor is coupled to the fourth node.

In a possible embodiment of the present disclosure, the shift register further includes a third node, a fourth node, a third node control sub-circuit and a fourth node control sub-circuit, the third node control sub-circuit is configured to control a potential at the third node, and the fourth node control sub-circuit is configured to control a potential at the fourth node; and the third node control sub-circuit is coupled to a second clock signal input end, a second level signal input end, the third node and the fourth node, and configured to control the second clock signal input end to be electrically coupled to or electrically decoupled from the third node under the control of the second clock signal input end, and further configured to control the second clock signal input end to be electrically coupled to or electrically decoupled from the third node under the control of the fourth node.

In a possible embodiment of the present disclosure, the third node control sub-circuit includes a second transistor and a third transistor; a gate electrode of the second transistor is coupled to the fourth node, a first node of the second transistor is coupled to the second clock signal input end, and a second electrode of the second transistor is coupled to the third mode; and a gate electrode of the third transistor is coupled to the second clock signal input end, a first electrode of the third transistor is coupled to the second level signal input end, and a second electrode of the third transistor is coupled to the third node.

In a possible embodiment of the present disclosure, the shift register further includes a third node, a fourth node, a third node control sub-circuit and a fourth node control sub-circuit, the third node control sub-circuit is configured to control a potential at the third node, and the fourth node control sub-circuit is configured to control a potential at the fourth node; and the fourth node control sub-circuit is coupled to an input signal end, the first clock signal input end, a second clock signal input end, the first level signal input, a third node and a fourth node, and configured to control the input signal end to be electrically coupled to or electrically decoupled from the fourth node under the control of the second clock signal input end, and further configured to control the first level signal input end to be electrically coupled to or electrically decoupled from the fourth node under the control of the third node and the first clock signal input end.

In a possible embodiment of the present disclosure, the fourth node control sub-circuit includes a first transistor, a sixth transistor and a seventh transistor; a gate electrode of the first transistor is coupled to the second clock signal input end, a first electrode of the first transistor is coupled to the input signal end, and a second electrode of the first transistor is coupled to the fourth node; a gate electrode of the sixth transistor is coupled to the third node, a first electrode of the sixth transistor is coupled to the first level signal input end, and a second electrode of the sixth transistor is coupled to a first electrode of the seventh transistor; and a gate electrode of the seventh transistor is coupled to the first clock signal input end, and a second electrode of the seventh transistor is coupled to the fourth node.

In a possible embodiment of the present disclosure, the first output sub-circuit includes a fourth transistor and a first capacitor, a gate electrode of the fourth transistor is coupled to the first node, a first electrode of the fourth transistor is coupled to the first level signal input end, a second electrode of the fourth transistor is coupled to the gate driving signal output end, a first end of the first capacitor is coupled to the first level signal input end, and a second end of the first capacitor is coupled to the first node; and the second output sub-circuit includes a fifth transistor and a second capacitor, a gate electrode of the fifth transistor is coupled to the second node, a first electrode of the fifth transistor is coupled to the first clock signal input end, a second electrode of the fifth transistor is coupled to the gate driving signal output end, a first end of the second capacitor is coupled to the second node, and a second end of the second capacitor is coupled to the gate driving signal output end.

In another aspect, the present disclosure provides in some embodiments a gate driving circuit, including a plurality of the above-mentioned shift registers cascaded to each other.

In yet another aspect, the present disclosure provides in some embodiments a display device including the above-mentioned gate driving circuit.

In still yet another aspect, the present disclosure provides in some embodiments a driving method for driving the above-mentioned shift register. The driving method includes a plurality of driving periods, and within one driving period, the driving method includes: at a maintenance stage, inputting a first voltage signal by a first clock signal input end and/or a second clock signal input end coupled to the shift register; and controlling, by a first output sub-circuit, a first level signal input end to be electrically coupled to a gate driving signal output end under the control of a first node; controlling, by a second output sub-circuit, the first clock signal input end to be electrically decoupled from the gate driving signal output end under the control of a second node; within at least a partial time period of the maintenance stage, substantially maintaining, by a first maintenance sub-circuit, a voltage at the first node in a first operating mode under the control of a control signal input end; and substantially maintaining, by a second maintenance sub-circuit, a voltage at the second node in the first operating mode under the control of the control signal input end.

In a possible embodiment of the present disclosure, the first maintenance sub-circuit includes a tenth transistor, the second maintenance sub-circuit includes a ninth transistor, and the ninth transistor and the tenth transistor include oxide transistors; and within at least a partial time period of the maintenance stage, the ninth transistor and the tenth transistor are turned off under the control of the control signal input end.

In a possible embodiment of the present disclosure, within one driving period, at a refreshing stage, a clock signal is inputted by the first clock signal input end and/or the second clock signal input end coupled to the shift register, and a ninth transistor and a tenth transistor are tumed on under the control of the control signal input end.

### BRIEF DESCRIPTION OF THE DRAWINGS

The following drawings are provided to facilitate the understanding of the present disclosure, and constitute a portion of the description. These drawings and the following embodiments are for illustrative purposes only, but shall not be construed as limiting the present disclosure. In these drawings,

FIG. 1 is a schematic view showing sub-circuits of a shift register according to one embodiment of the present disclosure;

FIG. 2 is another schematic view showing the sub-circuits of the shift register according to one embodiment of the present disclosure;

FIG. 3 is a schematic view showing the shift register according to one embodiment of the present disclosure;

FIG. 4 is another schematic view showing the shift register according to one embodiment of the present disclosure;

FIG. 5 is a sequence diagram of signals received by the shift register according to one embodiment of the present disclosure;

FIG. 6 is an enlarge view of A1 in FIG. 5;

FIG. 7 is yet another schematic view showing the shift register according to one embodiment of the present disclosure;

FIG. 8 is still yet another schematic view showing the shift register according to one embodiment of the present disclosure;

FIG. 9 is a sequence diagram of signals received by the shift register according to one embodiment of the present disclosure; and

FIG. 10 is an enlarged view of A2 in FIG. 9.

### DETAILED DESCRIPTION

The present disclosure will be described hereinafter in details in conjunction with the drawings and embodiments.

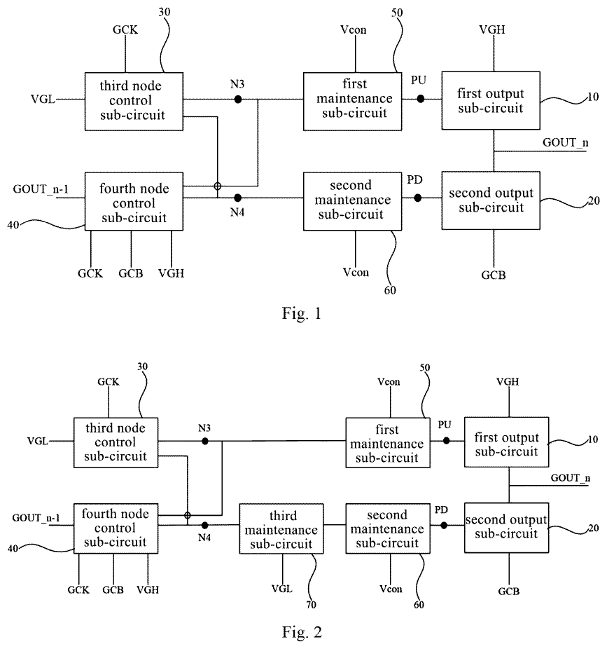

As shown in FIG. 1, and 7 to 10, the present disclosure provides in some embodiments a shift register, which includes a first node PU, a second node PD, a first output sub-circuit 10, and a second output sub-circuit 20. The shift register further includes a first maintenance sub-circuit 50 and/or a second maintenance sub-circuit 60. The first output sub-circuit 10 is coupled to a first level signal input end VGH, a gate driving signal output end (e.g., GOUT_n and GOUT_n+1) and the first node PU, and configured to control the first level signal input end VGH to be electrically coupled to or electrically decoupled from the gate driving signal output end under the control of the first node PU. The second output sub-circuit 20 is coupled to a first clock signal input end (for inputting a signal GCK or GCB), the gate driving signal output end and the second node PD, and configured to control the first clock signal input end to be electrically coupled to or electrically decoupled from the gate driving signal output end under the control of the second node PD. The first maintenance sub-circuit 50 is coupled to a control signal input end Vcon and the first node PU, and configured to substantially maintain a voltage at the first node in a first operating mode. The second maintenance sub-circuit 60 is coupled to the control signal input end Vcon and the second node PD. and configured to substantially maintain a voltage at the second node in the first operating mode.

For example, the first node PU includes, but not limited to, a pull-up node, and the second node PD includes, but not limited to, a pull-down node.

For example, the first level signal input end VGH inputs, but not limited to, a high level signal.

For example, the shift register further includes a third node N3, a fourth node N4, a third node control sub-circuit 30 and a fourth node control sub-circuit 40, the third node control sub-circuit 30 is configured to control a potential at the third node N3, and the fourth node control sub-circuit 40 is configured to control a potential at the fourth node N4.

The first maintenance sub-circuit 50 is coupled to the control signal input end Vcon, the first node PU and the third node N3, and configured to control the first node PU to be electrically coupled to or electrically decoupled from the third node N3 under the control of the control signal input end Vcon.

The second maintenance sub-circuit 60 is coupled to the control signal input end Vcon, the second node PD and the fourth node N4, and configured to control the second node PD to be electrically coupled to or electrically decoupled from the fourth node N4 under the control of the control signal input end Vcon.

For example, the first maintenance sub-circuit 50 includes a tenth transistor T10, a gate electrode of the tenth transistor T10 is coupled to the control signal input end Veon, a first electrode of the tenth transistor T10 is coupled to the first node PU, and a second electrode of the tenth transistor T10 is coupled to the third node N3. The second maintenance sub-circuit 60 includes a ninth transistor T9, a gate electrode of the ninth transistor T9 is coupled to the control signal input end Vcon, a first electrode of the ninth transistor T9 is coupled to the second node PD, and a second electrode of the ninth transistor T9 is coupled to the fourth node N4.

For example, the ninth transistor T9 and the tenth transistor T10 include oxide transistors.

For example, the shift register is applied to, but not limited to, low-frequency driving.

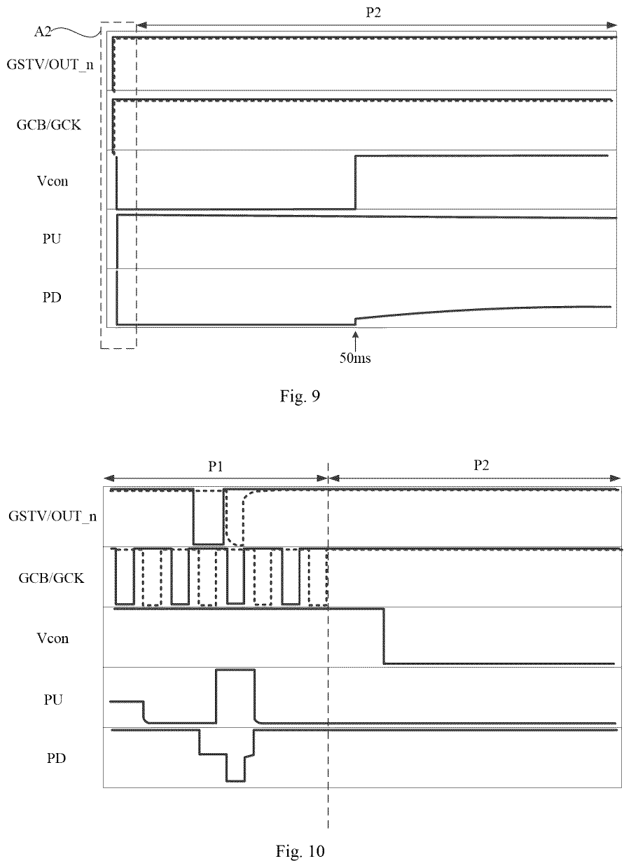

For example, in a case of low-frequency driving, as shown in FIG. 10, at a maintenance stage P2, a signal (e.g., GCK/GCB) inputted by the first clock signal input end and/or the second clock signal input end is set to be at a high potential within a long time period, i.e., a first voltage signal is inputted to replace an original clock signal in a high-frequency toggling mode. In addition, a control signal inputted by the control signal input end Vcon is adjusted to and maintained as a low voltage, and the ninth transistor T9 and the tenth transistor T10 are turned off, so that the first maintenance sub-circuit 50 and the second maintenance sub-circuit 60 are both in the first operating mode. Due to such a characteristic of the oxide transistor as low current leakage, the voltages at the first node PU and the second node PD remain unchanged, so that an output signal of the gate driving signal output end is maintained at a stable voltage. As shown in FIG. 9, as a comparison, the control signal is adjusted to be a high voltage at 50 ms, and it is found that a voltage drift gradually occurs for the first node PU and the second node PD, which is adverse to the maintenance of an output voltage of the gate driving signal output end.

It should be appreciated that, the maintenance stage P2 starts in a case that the signal (e.g., GCK/GCB) inputted by the first clock signal input end and/or the second clock signal input end is set to be at a high potential within a long time period. At the maintenance stage P2, in a case that the control signal inputted by the control signal input end Vcon is adjusted to and maintained as a low voltage, the first maintenance sub-circuit 50 and the second maintenance sub-circuit 60 enter the first operating mode.

For example, the shift register is used to output, but not limited to, a light-emission control signal or a gate scanning signal.

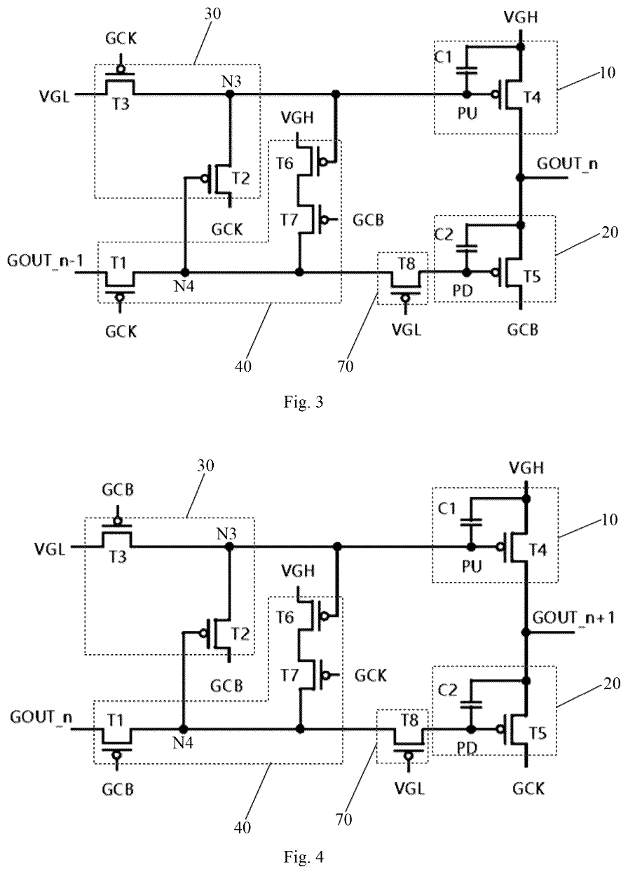

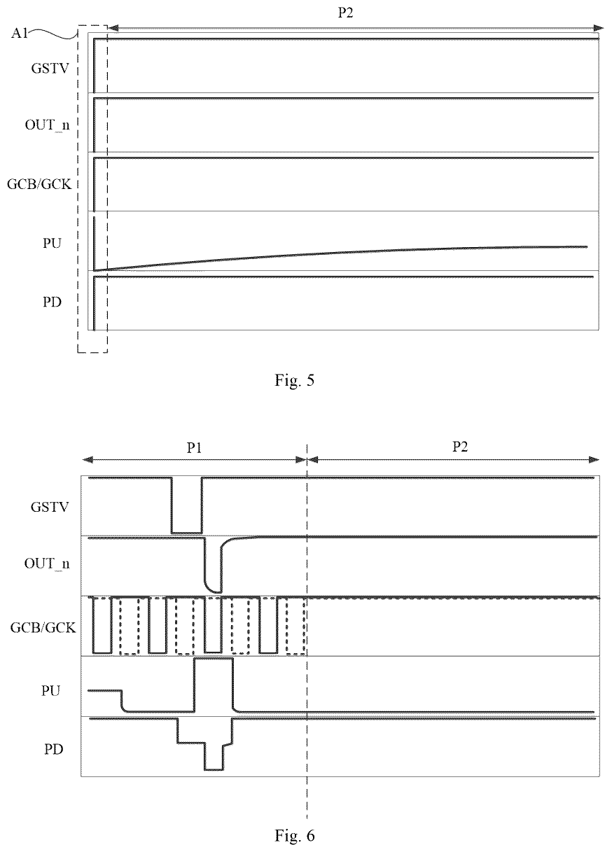

Based on the problems mentioned in the background, it is found through researches that, as shown in FIGS. 3, 4 and 6, in a case of low-frequency driving (e.g., 10 Hz), the gate driving signal output end needs to be maintained at a high voltage. At this time, the first node PU is maintained at a low voltage and the second node PD is maintained at a high voltage. A first clock signal inputted by the first clock signal input end and a second clock signal inputted by the second clock signal input end are always maintained in a high-frequency toggling state at a stage where the gate driving signal output end outputs a high voltage, which results in a large amount of power consumption. In a case that the clock signals inputted by the first clock signal input end and the second clock signal input end are adjusted to a first voltage signal maintained as a high voltage at the stage where the gate driving signal output end outputs a high voltage, it is able to remarkably reduce the power consumption of a gate driving circuit. As shown in FIG. 5, with the setting of the timing sequence, the gate driving signal output end performs normal output at an initial stage, and with the elapse of time, the gate driving signal output end outputs the high voltage unstably. This is because, after the clock signal is adjusted to the first voltage signal, the first node PU and the second node PD do not receive any signal for refreshing and thereby they are in a floating state, and the voltage drift gradually occurs for the nodes, so that the high voltage outputted by the gate driving signal output end becomes unstable.

Based on the above-mentioned specific structure of the shift register, the first maintenance sub-circuit 50 is coupled to the control signal input end and the first node PU, and configured to substantially maintain the voltage at the first node PU in the first operating mode; and the second maintenance sub-circuit 60 is coupled to the control signal input end and the second node PD, and configured to substantially maintain the voltage at the second node PD in the first operating mode. At the maintenance stage P2, the first voltage signal at a fixed potential is inputted by the clock signal input end coupled to the shift register, and the first maintenance sub-circuit 50 and the second maintenance sub-circuit 60 are in the first operating mode, so as to maintain the voltages at the first node PU and the second node PD, thereby to ensure the stability of the signal outputted by the gate driving signal output end.

Based on the above-mentioned specific structure of the shift register, the first maintenance sub-circuit 50 controls the first node PU to be electrically coupled to or electrically decoupled from the third node N3 under the control of the control signal input end Vcon, and the second maintenance sub-circuit 60 controls the second node PD to be electrically coupled to or electrically decoupled from the fourth node N4 under the control of the control signal input end Vcon.

Through this arrangement, during the operation of the shift register, at a refreshing stage P1, a toggling clock signal is inputted by the clock signal input end coupled to the shift register, the first maintenance sub-circuit 50 controls the first node PU to be electrically coupled to the third node N3, and the second maintenance sub-circuit 60 controls the second node PD to be electrically coupled to the fourth node N4, so as to achieve a driving function of the shift register. At the maintenance stage P2, the first voltage signal at a fixed voltage is inputted by the clock signal input end coupled to the shift register, the first maintenance sub-circuit 50 controls the first node PU to be electrically decoupled from the third node N3, and the second maintenance sub-circuit 60 controls the second node PD to be electrically decoupled from the fourth node N4, so as to maintain the voltages at the first node PU and the second node PD, thereby to ensure the stability of the signal outputted by the gate driving signal output end.

Hence, in the shift register provided in the embodiments of the present disclosure, it is able to ensure the driving function of the shift register at the refreshing stage P1. At the maintenance stage P2, the signal inputted by the clock signal input end is changed from a high-frequency toggling state to a fixed voltage maintenance state, so as to reduce the power consumption of the shift register. In addition, at the maintenance stage P2, the voltages at the first node PU and the second node PD are maintained by the first maintenance sub-circuit 50 and the second maintenance sub-circuit 60, so as to prevent the occurrence of the voltage drift for the first node PU and the second node PD at the maintenance stage, thereby to ensure the stability of the signal outputted by the gate driving signal output end. In a case that the shift register is applied to a gate driving circuit, it is able to reduce the power consumption generated by the gate driving circuit.

As shown in FIGS. 2, 7 and 8, in some embodiments of the present disclosure, the shift register further includes a third maintenance sub-circuit 70, and the third maintenance sub-circuit 70 is coupled to a second level signal input end VGL, the fourth node N4 and the second maintenance sub-circuit 60, and configured to control the fourth node N4 to be electrically coupled to or electrically decoupled from the second maintenance sub-circuit 60 under the control of the second level signal input end VGL.

For example, the third maintenance sub-circuit 70 includes an eighth transistor T8, a gate electrode of the eighth transistor T8 is coupled to the second level signal input end VGL, a first electrode of the eighth transistor T8 is coupled to the second maintenance sub-circuit 60, and a second electrode of the eighth transistor T8 is coupled to the fourth node N4. The second level signal input end VGL is configured to control the eighth transistor TS to be turned on or off.

For example, the second level signal input end VGL inputs, but not limited to, a low level signal.

For example, the eighth transistor T8 includes, but not limited to, an LTPS transistor.

Through the third maintenance sub-circuit 70, it is able to ensure that a gate-to-source voltage Vds of the first transistor T1 is not too large at all stages.

As shown in FIGS. 2, 7 and 8, in some embodiments of the present disclosure, the third node control sub-circuit 30 is coupled to a second clock signal input end, a second level signal input end VGL, the third node N3 and the fourth node N4, and configured to control the second clock signal input end to be electrically coupled to or electrically decoupled from the third node N3 under the control of the second clock signal input end, and further configured to control the second clock signal input end to be electrically coupled to or electrically decoupled from the third node N3 under the control of the fourth node N4.

For example, the third node control sub-circuit 30 includes a second transistor T2 and a third transistor T3. A gate electrode of the second transistor T2 is coupled to the fourth node N4, a first node of the second transistor T2 is coupled to the second clock signal input end, and a second electrode of the second transistor T2 is coupled to the third node N3. The fourth node N4 is configured to control the second transistor T2 to be turned on or off. A gate electrode of the third transistor T3 is coupled to the second clock signal input end, a first electrode of the third transistor T3 is coupled to the second level signal input end VGL, and a second electrode of the third transistor T3 is coupled to the third node N3. The second clock signal input end is configured to control the third transistor T3 to be turned on or off.

As shown in FIGS. 2, 7 and 8, in some embodiments of the present disclosure, the fourth node control sub-circuit 40 is coupled to an input signal end (e.g., GOUT_n and GOUT_n−1), the first clock signal input end, a second clock signal input end, the first level signal input VGH, a third node N3 and a fourth node N4, and configured to control the input signal end to be electrically coupled to or electrically decoupled from the fourth node N4 under the control of the second clock signal input end, and further configured to control the first level signal input end VGH to be electrically coupled to or electrically decoupled from the fourth node N4 under the control of the third node N3 and the first clock signal input end.

For example, the fourth node control sub-circuit 40 includes a first transistor T1, a sixth transistor T6 and a seventh transistor T7. A gate electrode of the first transistor T1 is coupled to the second clock signal input end, a first electrode of the first transistor T1 is coupled to the input signal end, and a second electrode of the first transistor T1 is coupled to the fourth node N4. The second clock signal input end is configured to control the first transistor T1 to be turned on or off. A gate electrode of the sixth transistor T6 is coupled to the third node N3, a first electrode of the sixth transistor T6 is coupled to the first level signal input end VGH, and a second electrode of the sixth transistor T6 is coupled to a first electrode of the seventh transistor T7. The third node N3 is configured to control the sixth transistor T6 to be turned on or off. A gate electrode of the seventh transistor T7 is coupled to the first clock signal input end, and a second electrode of the seventh transistor T7 is coupled to the fourth node N4. The first clock signal input end is configured to control the seventh transistor T7 to be turned on or off.

As shown in FIGS. 2, 7 and 8, in some embodiments of the present disclosure, the first output sub-circuit 10 includes a fourth transistor T4 and a first capacitor C1, a gate electrode of the fourth transistor T4 is coupled to the first node PU, a first electrode of the fourth transistor T4 is coupled to the first level signal input end VGH, a second electrode of the fourth transistor T4 is coupled to the gate driving signal output end, a first end of the first capacitor C1 is coupled to the first level signal input end VGH, and a second end of the first capacitor C1 is coupled to the first node PU. The first node PU is configured to control the fourth transistor T4 to be turned on or off.

The second output sub-circuit 20 includes a fifth transistor T5 and a second capacitor C2, a gate electrode of the fifth transistor T5 is coupled to the second node PD, a first electrode of the fifth transistor T5 is coupled to the first clock signal input end, a second electrode of the fifth transistor T5 is coupled to the gate driving signal output end, a first end of the second capacitor C2 is coupled to the second node PD, and a second end of the second capacitor C2 is coupled to the gate driving signal output end. The second node PD is configured to control the fifth transistor T5 to be turned on or off.

For example, in the shift register, the first transistor T1, the second transistor T2, the third transistor T3, the fourth transistor T4, the fifth transistor T5, the sixth transistor T6, the seventh transistor T7 and the eighth transistor T8 include, but not limited to, LTPS transistors, and the ninth transistor T9 and the tenth transistor T10 include, but not limited to, oxide transistors.

The present disclosure further provides a gate driving circuit, including a plurality of the above-mentioned shift registers cascaded to each other.

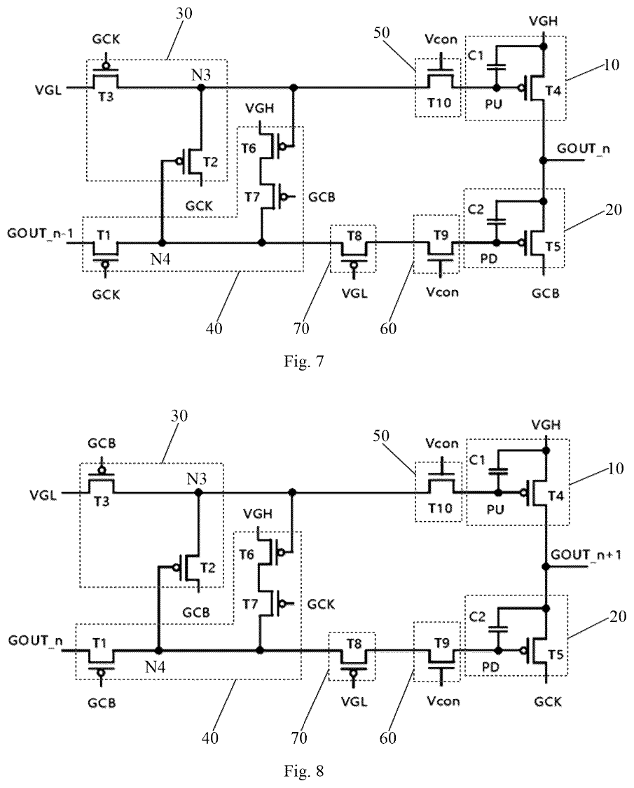

As shown in FIGS. 7 and 8, for example, in adjacent two levels of shift registers, a gate driving signal output end GOUT_n of a first-level shift register is coupled to an input signal end of a second-level shift register.

For example, in adjacent two levels of shift registers, a signal (e.g., GCB) inputted by a first clock signal input end coupled to a first-level shift register is the same as a signal (e.g., GCB) inputted by a second clock signal input end coupled to a second-level shift register, and a signal (GCK) inputted by a second clock signal input end of the first-level shift register is the same as a signal (e.g., GCK) inputted by a first clock signal input end of the second-level shift register. However, the present disclosure is not limited thereto.

It should be appreciated that, FIG. 9 further shows a frame start signal GSTV.

During the operation of the shift register, at a refreshing stage P1, a toggling clock signal is inputted by the clock signal input end coupled to the shift register, the first maintenance sub-circuit 50 controls the first node PU to be electrically coupled to the third node N3, and the second maintenance sub-circuit 60 controls the second node PD to be electrically coupled to the fourth node N4, so as to achieve a driving function of the shift register. At the maintenance stage P2, the first voltage signal at a fixed voltage is inputted by the clock signal input end coupled to the shift register, the first maintenance sub-circuit 50 controls the first node PU to be electrically decoupled from the third node N3, and the second maintenance sub-circuit 60 controls the second node PD to be electrically decoupled from the fourth node N4, so as to maintain the voltages at the first node PU and the second node PD, thereby to ensure the stability of the signal outputted by the gate driving signal output end. In the shift register provided in the embodiments of the present disclosure, it is able to ensure the driving function of the shift register at the refreshing stage P1. At the maintenance stage P2, the signal inputted by the clock signal input end is changed from a high-frequency toggling state to a fixed voltage maintenance state, so as to reduce the power consumption of the shift register. In addition, at the maintenance stage P2, the voltages at the first node PU and the second node PD are maintained by the first maintenance sub-circuit 50 and the second maintenance sub-circuit 60, so as to prevent the occurrence of the voltage drift for the first node PU and the second node PD at the maintenance stage, thereby to ensure the stability of the signal outputted by the gate driving signal output end. In a case that the gate driving circuit includes the shift register, it is able to reduce the power consumption generated by the gate driving circuit, and ensure the stability of the signal outputted by the gate driving circuit.

The present disclosure further provides in some embodiments a display device, which includes the above-mentioned gate driving circuit.

It should be appreciated that, the display device may be any product or member having a display function, e.g., television, display, digital photo frame, mobile phone, or tablet computer. The display device further includes a flexible circuit board, a printed circuit board, a back plate, etc.

Based on the gate driving circuit in the embodiments of the present disclosure, it is able to reduce the power consumption generated by the gate driving circuit, and ensure the stability of the signal outputted by the gate driving circuit. In a case that the display device includes the gate driving circuit, it also has the above-mentioned beneficial effects, which will not be particularly defined herein.

The present disclosure further provides in some embodiments a driving method for driving the above-mentioned shift register. The driving method includes a plurality of driving periods. As shown in FIGS. 9 and 10, within one driving period, the driving method includes: at a maintenance stage P2, inputting a first voltage signal by a first clock signal input end and/or a second clock signal input end coupled to the shift register; and controlling, by a first output sub-circuit 10, a first level signal input end VGH to be electrically coupled to a gate driving signal output end under the control of a first node PU; controlling, by a second output sub-circuit 20, the first clock signal input end to be electrically decoupled from the gate driving signal output end under the control of a second node PD; within at least a partial time period of the maintenance stage P2, substantially maintaining, by a first maintenance sub-circuit 50, a voltage at the first node PU in a first operating mode under the control of a control signal input end Vcon; and substantially maintaining, by a second maintenance sub-circuit 60, a voltage at the second node PD in the first operating mode under the control of the control signal input end Vcon.

For example, within at least a partial time period of the maintenance stage P2, the first maintenance sub-circuit 50 controls the first node PU to be electrically decoupled from the third node N3 under the control of the control signal input end Vcon, and within at least a partial time period of the maintenance stage P2, the second maintenance sub-circuit 60 controls the second node PD to be electrically coupled to the fourth node N4 under the control of the control signal input end Vcon.

For example, the first maintenance sub-circuit 50 includes a tenth transistor T10, the second maintenance sub-circuit 60 includes a ninth transistor T9, and the ninth transistor T9 and the tenth transistor T10 include oxide transistors. Within at least a partial time period of the maintenance stage P2, the ninth transistor T9 and the tenth transistor T10 are turned off under the control of the control signal input end Vcon.

For example, one driving periods includes a refreshing stage P1 and the maintenance stage P2. At the refreshing stage P1, a clock signal is inputted by the first clock signal input end and/or the second clock signal input end coupled to the shift register, and this clock signal is a high-frequency toggling signal. The ninth transistor T9 and the tenth transistor T10 are turned on under the control of the control signal input end Vcon. At the maintenance stage P2, a first voltage signal is inputted by the first clock signal input end and/or the second clock signal input end coupled to the shift register, and the ninth transistor T9 and the tenth transistor T10 are turned off under the control of the control signal input end Vcon.

In the shift register provided in the embodiments of the present disclosure, the first maintenance sub-circuit 50 controls the first node PU to be electrically coupled to or electrically decoupled from the third node N3 under the control of the control signal input end Vcon, and the second maintenance sub-circuit 60 controls the second node PD to be electrically coupled to or electrically decoupled from the fourth node N4 under the control of the control signal input end Vcon.

In a case that the driving method is used to drive the above-mentioned shift register, at the refreshing stage P1, a toggling clock signal is inputted by the clock signal input end coupled to the shift register, the first maintenance sub-circuit 50 controls the first node PU to be electrically coupled to the third node N3, and the second maintenance sub-circuit 60 controls the second node PD to be electrically coupled to the fourth node N4, so as to achieve a driving function of the shift register. At the maintenance stage P2, the first voltage signal at a fixed voltage is inputted by the clock signal input end coupled to the shift register, the first maintenance sub-circuit 50 controls the first node PU to be electrically decoupled from the third node N3, and the second maintenance sub-circuit 60 controls the second node PD to be electrically decoupled from the fourth node N4, so as to maintain the voltages at the first node PU and the second node PD, thereby to ensure the stability of the signal outputted by the gate driving signal output end.

Hence, in a case that the driving method is used to drive the above-mentioned shift register, it is able to ensure the driving function of the shift register at the refreshing stage P1. At the maintenance stage P2, the signal inputted by the clock signal input end is changed from a high-frequency toggling state to a fixed voltage maintenance state, so as to reduce the power consumption of the shift register. In addition, at the maintenance stage P2, the voltages at the first node PU and the second node PD are maintained by the first maintenance sub-circuit 50 and the second maintenance sub-circuit 60, so as to prevent the occurrence of the voltage drift for the first node PU and the second node PD at the maintenance stage, thereby to ensure the stability of the signal outputted by the gate driving signal output end. In a case that the shift register is applied to a gate driving circuit, it is able to reduce the power consumption generated by the gate driving circuit.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are merely for illustrative purposes, but shall not be construed as limiting the scope of the present disclosure. Any person skilled in the art may make modifications and substitutions without departing from the spirit of the present disclosure, and these modifications and substitutions shall also fall within the scope of the present disclosure. Hence, the scope of the present disclosure shall be subject to the scope defined by the appended claims.

1. A shift register, comprising a first node, a second node, a first output sub-circuit, and a second output sub-circuit, wherein the shift register further comprises a first maintenance sub-circuit and/or a second maintenance sub-circuit;
the first output sub-circuit is coupled to a first level signal input end, a gate driving signal output end and the first node, and configured to control the first level signal input end to be electrically coupled to or electrically decoupled from the gate driving signal output end under the control of the first node;
the second output sub-circuit is coupled to a first clock signal input end, the gate driving signal output end and the second node, and configured to control the first clock signal input end to be electrically coupled to or electrically decoupled from the gate driving signal output end under the control of the second node;
the first maintenance sub-circuit is coupled to a control signal input end and the first node, and configured to substantially maintain a voltage at the first node in a first operating mode; and
the second maintenance sub-circuit is coupled to the control signal input end and the second node, and configured to substantially maintain a voltage at the second node in the first operating mode.

2. The shift register according to claim 1, further comprising a third node, a fourth node, a third node control sub-circuit and a fourth node control sub-circuit, wherein the third node control sub-circuit is configured to control a potential at the third node, and the fourth node control sub-circuit is configured to control a potential at the fourth node;
the first maintenance sub-circuit comprises a tenth transistor, a gate electrode of the tenth transistor is coupled to the control signal input end, a first electrode of the tenth transistor is coupled to the first node, and a second electrode of the tenth transistor is coupled to the third node; and
the second maintenance sub-circuit comprises a ninth transistor, a gate electrode of the ninth transistor is coupled to the control signal input end, a first electrode of the ninth transistor is coupled to the second node, and a second electrode of the ninth transistor is coupled to the fourth node.

3. The shift register according to claim 2, wherein the ninth transistor and the tenth transistor comprise oxide transistors.

4. The shift register according to claim 1, further comprising a fourth node and a fourth node control sub-circuit, wherein the fourth node control sub-circuit is configured to control a potential at the fourth node; and
the shift register further comprises a third maintenance sub-circuit, and the third maintenance sub-circuit is coupled to a second level signal input end, the fourth node and the second maintenance sub-circuit, and configured to control the fourth node to be electrically coupled to or electrically decoupled from the second maintenance sub-circuit under the control of the second level signal input end.

5. The shift register according to claim 4, wherein the third maintenance sub-circuit comprises an eighth transistor, a gate electrode of the eighth transistor is coupled to the second level signal input end, a first electrode of the eighth transistor is coupled to the second maintenance sub-circuit, and a second electrode of the eighth transistor is coupled to the fourth node.

6. The shift register according to claim 1, further comprising a third node, a fourth node, a third node control sub-circuit and a fourth node control sub-circuit, wherein the third node control sub-circuit is configured to control a potential at the third node, and the fourth node control sub-circuit is configured to control a potential at the fourth node; and
the third node control sub-circuit is coupled to a second clock signal input end, a second level signal input end, the third node and the fourth node, and configured to control the second clock signal input end to be electrically coupled to or electrically decoupled from the third node under the control of the second clock signal input end, and further configured to control the second clock signal input end to be electrically coupled to or electrically decoupled from the third node under the control of the fourth node.

7. The shift register according to claim 6, wherein the third node control sub-circuit comprises a second transistor and a third transistor;
a gate electrode of the second transistor is coupled to the fourth node, a first node of the second transistor is coupled to the second clock signal input end, and a second electrode of the second transistor is coupled to the third node; and
a gate electrode of the third transistor is coupled to the second clock signal input end, a first electrode of the third transistor is coupled to the second level signal input end, and a second electrode of the third transistor is coupled to the third node.

8. The shift register according to claim 1, further comprising a third node, a fourth node, a third node control sub-circuit and a fourth node control sub-circuit, wherein the third node control sub-circuit is configured to control a potential at the third node, and the fourth node control sub-circuit is configured to control a potential at the fourth node; and
the fourth node control sub-circuit is coupled to an input signal end, the first clock signal input end, a second clock signal input end, the first level signal input, a third node and a fourth node, and configured to control the input signal end to be electrically coupled to or electrically decoupled from the fourth node under the control of the second clock signal input end, and further configured to control the first level signal input end to be electrically coupled to or electrically decoupled from the fourth node under the control of the third node and the first clock signal input end.

9. The shift register according to claim 8, wherein the fourth node control sub-circuit comprises a first transistor, a sixth transistor and a seventh transistor;
a gate electrode of the first transistor is coupled to the second clock signal input end, a first electrode of the first transistor is coupled to the input signal end, and a second electrode of the first transistor is coupled to the fourth node;
a gate electrode of the sixth transistor is coupled to the third node, a first electrode of the sixth transistor is coupled to the first level signal input end, and a second electrode of the sixth transistor is coupled to a first electrode of the seventh transistor; and
a gate electrode of the seventh transistor is coupled to the first clock signal input end, and a second electrode of the seventh transistor is coupled to the fourth node.

10. The shift register according to claim 1, wherein the first output sub-circuit comprises a fourth transistor and a first capacitor, a gate electrode of the fourth transistor is coupled to the first node, a first electrode of the fourth transistor is coupled to the first level signal input end, a second electrode of the fourth transistor is coupled to the gate driving signal output end, a first end of the first capacitor is coupled to the first level signal input end, and a second end of the first capacitor is coupled to the first node; and
the second output sub-circuit comprises a fifth transistor and a second capacitor, a gate electrode of the fifth transistor is coupled to the second node, a first electrode of the fifth transistor is coupled to the first clock signal input end, a second electrode of the fifth transistor is coupled to the gate driving signal output end, a first end of the second capacitor is coupled to the second node, and a second end of the second capacitor is coupled to the gate driving signal output end.

11. A gate driving circuit, comprising a plurality of cascaded shift registers, wherein the shift register comprises a first node, a second node, a first output sub-circuit, and a second output sub-circuit, wherein the shift register further comprises a first maintenance sub-circuit and/or a second maintenance sub-circuit;
the first output sub-circuit is coupled to a first level signal input end, a gate driving signal output end and the first node, and configured to control the first level signal input end to be electrically coupled to or electrically decoupled from the gate driving signal output end under the control of the first node;
the second output sub-circuit is coupled to a first clock signal input end the gate driving signal output end and the second node. and configured to control the first clock signal input end to be electrically coupled to or electrically decoupled from the gate driving signal output end under the control of the second node;
the first maintenance sub-circuit is coupled to a control signal input end and the first node. and configured to substantially maintain a voltage at the first node in a first operating mode; and
the second maintenance sub-circuit is coupled to the control signal input end and the second node, and configured to substantially maintain a voltage at the second node in the first operating mode.

12. A display device, comprising the gate driving circuit according to claim 11.

13. A driving method for driving the shift register according to claim 1, wherein the driving method includes a plurality of driving periods, and within one driving period, the driving method comprises:
at a maintenance stage, inputting a first voltage signal by a first clock signal input end and/or a second clock signal input end coupled to the shift register; and
controlling, by a first output sub-circuit, a first level signal input end to be electrically coupled to a gate driving signal output end under the control of a first node;
controlling, by a second output sub-circuit, the first clock signal input end to be electrically decoupled from the gate driving signal output end under the control of a second node;
within at least a partial time period of the maintenance stage, substantially maintaining, by a first maintenance sub-circuit, a voltage at the first node in a first operating mode under the control of a control signal input end; and
substantially maintaining, by a second maintenance sub-circuit, a voltage at the second node in the first operating mode under the control of the control signal input end.

14. The driving method according to claim 13, wherein the first maintenance sub-circuit comprises a tenth transistor, the second maintenance sub-circuit comprises a ninth transistor, and the ninth transistor and the tenth transistor comprise oxide transistors; and within at least a partial time period of the maintenance stage, the ninth transistor and the tenth transistor are turned off under the control of the control signal input end.

15. The driving method according to claim 13, wherein within one driving period, at a refreshing stage, a clock signal is inputted by the first clock signal input end and/or the second clock signal input end coupled to the shift register; and
a ninth transistor and a tenth transistor are turned on under the control of the control signal input end.

16. The gate driving circuit according to claim 11, wherein the shift register further comprises a third node, a fourth node, a third node control sub-circuit and a fourth node control sub-circuit, wherein the third node control sub-circuit is configured to control a potential at the third node, and the fourth node control sub-circuit is configured to control a potential at the fourth node;
the first maintenance sub-circuit comprises a tenth transistor, a gate electrode of the tenth transistor is coupled to the control signal input end, a first electrode of the tenth transistor is coupled to the first node, and a second electrode of the tenth transistor is coupled to the third node; and
the second maintenance sub-circuit comprises a ninth transistor, a gate electrode of the ninth transistor is coupled to the control signal input end, a first electrode of the ninth transistor is coupled to the second node, and a second electrode of the ninth transistor is coupled to the fourth node.

17. The gate driving circuit according to claim 16, wherein the ninth transistor and the tenth transistor comprise oxide transistors.

18. The gate driving circuit according to claim 11, wherein the shift register further comprises a fourth node and a fourth node control sub-circuit, wherein the fourth node control sub-circuit is configured to control a potential at the fourth node; and
the shift register further comprises a third maintenance sub-circuit, and the third maintenance sub-circuit is coupled to a second level signal input end, the fourth node and the second maintenance sub-circuit, and configured to control the fourth node to be electrically coupled to or electrically decoupled from the second maintenance sub-circuit under the control of the second level signal input end.

19. The gate driving circuit according to claim 18, wherein the third maintenance sub-circuit comprises an eighth transistor, a gate electrode of the eighth transistor is coupled to the second level signal input end, a first electrode of the eighth transistor is coupled to the second maintenance sub-circuit, and a second electrode of the eighth transistor is coupled to the fourth node.

20. The gate driving circuit according to claim 11, wherein the shift register further comprises a third node, a fourth node, a third node control sub-circuit and a fourth node control sub-circuit, wherein the third node control sub-circuit is configured to control a potential at the third node, and the fourth node control sub-circuit is configured to control a potential at the fourth node; and
the third node control sub-circuit is coupled to a second clock signal input end, a second level signal input end, the third node and the fourth node, and configured to control the second clock signal input end to be electrically coupled to or electrically decoupled from the third node under the control of the second clock signal input end, and further configured to control the second clock signal input end to be electrically coupled to or electrically decoupled from the third node under the control of the fourth node.
